(19) United States
(12) Patent Application Publication
(10) Pub. No.: US 2026/0269000 A1
(43) Pub. Date: Sep. 10, 2026

(54) DETECTING AND CORRECTING SINGLE EVENT UPSETS IN STATIC RANDOM-ACCESS MEMORY CELLS

(71) Applicant: Xilinx, Inc., San Jose, CA (US)

(72) Inventors: Kumar Rahul, Hyderabad (IN); Mrinmoy Goswami, Paschim Medinipur (IN); Gokul Puthenpurayil Ravindran, Kollam (IN); Santosh Yachareni, Hyderabad (IN)

(73) Assignee: Xilinx, Inc., San Jose, CA (US)

(21) Appl. No.: 19/071,584

(22) Filed: Mar. 5, 2025

(51) Int. Cl. G11C 29/52; G11C 11/418; G11C 11/419

(52) U.S. Cl. CPC G11C 29/52; G11C 11/418; G11C 11/419

(57) ABSTRACT

A memory circuit includes a memory cell including a plurality of inverter pairs. The plurality of inverter pairs include a first inverter pair and one or more reference inverter pairs. The plurality of inverter pairs are coupled by access transistors to same bit lines and to a same word line. The memory circuit includes a detector circuit coupled to the plurality of inverter pairs. The detector circuit is capable of generating an indicator signal in response to detecting a single-event upset (SEU) in the memory cell by detecting a mismatch in stored states among the plurality of inverter pairs of the memory cell. The memory circuit may include a correction circuit capable of correcting an output of the memory cell.

### TECHNICAL FIELD

This disclosure relates to integrated circuits (ICs). More particularly, this disclose relates to detecting and correcting single event upset (SEUs) in static random-access memory (SRAM) cells.

### BACKGROUND

A single-event upset (SEU) refers to a change of state of a memory cell, e.g., a change from zero to one or a change from one to zero, induced by an energetic particle such as a cosmic ray, a proton, or the like, striking a device. SEUs are generally referred to as “soft” errors in that a reset or rewriting of the memory cells of the device typically causes normal device behavior after the occurrence of the SEU. SEUs can manifest themselves within digital, analog, and optical components of a system or may have effects in surrounding interface circuitry. In practical terms, a change in state typically causes an error or system fault.

The occurrence of an SEU may have significant consequences in any of a variety of different types of devices and/or systems. Within devices that include some level of programmable or adaptable circuitry, the occurrence of an SEU can be particularly problematic. Many devices that provide programmability, e.g., are adaptable after being released into the field, store configuration data in memory cells. The configuration data dictates how particular circuit blocks of the device are to be used or how such circuit blocks will function. An SEU occurrence in such a memory cell may have serious consequences by altering the intended function of the circuit block(s) controlled by that memory cell.

To avoid the potentially serious consequences from the occurrence of an SEU, many ICs implement a “read back” or “scrubbing” functionality. Read back refers to reading the contents of memory cells, comparing the contents of the memory cells to reference data, and correcting the data in the memory cells in the case of a mismatch by writing correct data to the memory cells. Because read back functionality implements memory reads and writes, this capability may consume significant power. Further, because the occurrence of an SEU is not itself detected, but rather is detected only by virtue of detecting an SEU induced error in the system, conventional approaches for contending with SEUs implemented read back on a periodic basis. This leaves open the possibility that incorrect data will exist in SEU-corrupted memory cell(s) for some period of time.

### SUMMARY

In one or more examples, a memory circuit includes a memory cell. The memory cell includes a plurality of inverter pairs including a first inverter pair and one or more reference inverter pairs. The plurality of inverter pairs are coupled by access transistors to same bit lines and to a same word line. The memory circuit includes a detector circuit coupled to the plurality of inverter pairs. The detector circuit is capable of generating an indicator signal in response to detecting a single-event upset (SEU) in the memory cell by detecting a mismatch in stored states among the plurality of inverter pairs of the memory cell.

The foregoing and other implementations can each optionally include one or more of the following features, alone or in combination. Some example implementations include all the following features in combination.

In some aspects, each inverter pair of the plurality of inverter pairs is cross-coupled.

In some aspects, the one or more reference inverter pairs include a second inverter pair. The detector circuit is coupled to an output node and an inverted output node of the first inverter pair and is coupled to a first reference output node and a first inverted reference output node of the second inverter pair.

In some aspects, the detector circuit includes a first pair of series transistors coupled to the first inverted reference output node of the second inverter pair and the output node of the first inverter pair. The detector circuit also includes a second pair of series transistors coupled to the inverted output node of the first inverter pair and the first reference output node of the second inverter pair.

In some aspects, a gate of a first transistor of the first pair of series transistors is coupled to the first inverted reference output node. A gate of a second transistor of the first pair of series transistors is coupled to the output node. A gate of a first transistor of the second pair of series transistors is coupled to the inverted output node. A gate of a second transistor of the second pair of series transistors is coupled to the first reference output node.

In some aspects, the one or more reference inverter pairs include a third inverter pair and the output node provides an output signal from the memory cell. The memory circuit further includes a correction circuit coupled to the output node and capable of outputting a corrected output signal for the memory cell.

In some aspects, the third inverter pair is cross-coupled.

In some aspects, the correction circuit is capable of generating the corrected output signal as a function of signals from the output node, the inverted output node, the first reference output node, and the first inverted reference output node, and a second reference output node of the third inverter pair and a second inverted reference output node of the third inverter pair.

In some aspects, the detector circuit includes a first pair of series transistors coupled to the output node and the second inverted reference output node, a second pair of series transistors coupled to the first inverted reference output node and the second reference output node, and a third pair of series transistors coupled to the inverted output node and the first reference output node.

In some aspects, a gate of a first transistor of the first pair of series transistors is coupled to the output node; a gate of a second transistor of the first pair of series transistors is coupled to the second inverted reference output node; a gate of a first transistor of the second pair of series transistors is coupled to the first inverted reference output node; a gate of a second transistor of the second pair of series transistors is coupled to the second reference output node; a gate of a first transistor of the third pair of series transistors is coupled to the inverted output node; and a gate of a second transistor of the third pair of series transistors is coupled to the first reference output node.

In some aspects, a controller circuit is capable of initiating a read back function on the memory cell in response to detecting the indicator signal.

In one or more examples, a method includes providing a memory cell having a plurality of inverter pairs. Each inverter pair is coupled to same bit lines and to a same word line and stores a same state. The method includes monitoring the state of each inverter pair of the memory cell during operation by a detector circuit comparing the states of plurality of inverter pairs. The method includes, in response to detecting that at least one inverter pair is storing a different state than at least one other inverter pair of the memory cell, generating a flag, by the detector circuit, indicating an occurrence of an SEU.

The foregoing and other implementations can each optionally include one or more of the following features, alone or in combination. Some example implementations include all the following features in combination.

In some aspects, the method includes initiating a read back function on the memory cell in response to detecting the flag.

In some aspects, the read back function is implemented only for a subset of one or more instances of a memory circuit architecture of a plurality of instances of the memory circuit architecture that include the memory cell in which the SEU was detected.

In some aspects, the plurality of inverter pairs of the memory cell include a first inverter pair and a second inverter pair. Each inverter pair is cross-coupled.

In some aspects, the detector circuit includes a first pair of series transistors coupled to an inverted reference output node of the second inverter pair and an output node of the first inverter pair. The detector circuit also includes a second pair of series transistors coupled to an inverted output node of the first inverter pair and a first reference output node of the second inverter pair.

In some aspects, the method includes generating a corrected output signal in response to detecting that the at least one inverter pair storing the different state is a selected inverter pair of the plurality of inverter pairs that generates an output signal for the memory cell.

In some aspects, the plurality of inverter pairs of the memory cell include a first inverter pair, a second inverter pair, and a third inverter pair, wherein the second and third inverter pairs are reference inverter pairs. The corrected output signal is generated as a function of signals from an output node and an inverted output node of the first inverter pair, a first reference output node and a first inverted reference output node of the second inverter pair, and a second reference output node and a second inverted reference output node of the third inverter pair.

In one or more examples, an integrated circuit includes a plurality of instances of a memory circuit architecture. The memory circuit architecture includes a memory cell including a plurality of inverter pairs including a first inverter pair and one or more reference inverter pairs. The plurality of inverter pairs are coupled by access transistors to same bit lines and to a same word line. The memory circuit architecture includes a detector circuit coupled to the plurality of inverter pairs. The detector circuit is capable of generating an indicator signal in response to detecting an SEU in the memory cell by detecting a mismatch in stored states among the plurality of inverter pairs of the memory cell. The memory circuit architecture includes a correction circuit coupled to an output node of the first inverter pair. The correction circuit is capable of outputting a corrected output signal for the memory cell. The plurality of inverter pairs of the plurality of instances of the memory circuit architecture are interdigitated.

The foregoing and other implementations can each optionally include one or more of the following features, alone or in combination. Some example implementations include all the following features in combination.

In some aspects, a read back function is implemented for at least one instance of the plurality of instances of the memory circuit architecture in which the SEU occurred in response to the indicator signal from the detector circuit.

This Summary section is provided merely to introduce certain concepts and not to identify any key or essential features of the claimed subject matter. Many other features and implementations of the disclosed technology will be apparent from the accompanying drawings and from the following detailed description.

### BRIEF DESCRIPTION OF THE DRAWINGS

The accompanying drawings show one or more implementations of the disclosed technology. The drawings, however, should not be construed to be limiting of the implementations to only the examples shown. Various aspects and advantages will become apparent upon review of the following detailed description and upon reference to the drawings.

FIG. 1 illustrates an example memory cell of a memory circuit architecture in accordance with one or more implementations of the disclosed technology.

FIG. 2 illustrates an example detector circuit of a memory circuit architecture in accordance with one or more implementations of the disclosed technology.

FIG. 3 illustrates a table depicting different scenarios in which the flag signal is triggered in accordance with one or more implementations of the disclosed technology.

FIG. 4 illustrates another example memory cell of a memory circuit architecture in accordance with one or more implementations of the disclosed technology.

FIG. 5 illustrates another example detector circuit of a memory circuit architecture in accordance with one or more implementations of the disclosed technology.

FIG. 6 illustrates an example of a correction circuit in accordance with one or more implementations of the disclosed technology.

FIG. 7 illustrates a table depicting different scenarios in which the memory cell output is corrected and the flag signal of a memory circuit architecture is triggered in accordance with one or more implementations of the disclosed technology.

FIGS. 8A and 8B illustrate example layouts of a memory circuit architecture in accordance with one or more implementations of the disclosed technology.

FIGS. 9A and 9B illustrate the state of different signals of the memory circuit architecture of FIGS. 4, 5, 6, and 7 under different conditions.

FIG. 10 illustrates an example memory formed of a plurality of instances of the memory circuit architecture described herein in accordance with one or more implementations of the disclosed technology.

FIG. 11 illustrates a method of operation of a memory circuit architecture in accordance with one or more implementations of the disclosed technology.

### DETAILED DESCRIPTION

While the disclosure concludes with claims defining novel features, it is believed that the various features described within this disclosure will be better understood from a consideration of the description in conjunction with the drawings. The process(es), machine(s), manufacture(s) and any variations thereof described herein are provided for purposes of illustration. Specific structural and functional details described within this disclosure are not to be interpreted as limiting, but merely as a basis for the claims and as a representative basis for teaching one skilled in the art to variously employ the features described in virtually any appropriately detailed structure. Further, the terms and phrases used within this disclosure are not intended to be limiting, but rather to provide an understandable description of the features described.

This disclosure relates to integrated circuits (ICs) and, more particularly, to detecting and correcting single-event upset (SEUs) in static random-access memory (SRAM) cells. In accordance with the implementations described within this disclosure, example memory circuit architectures are disclosed that are capable of detecting the occurrence of an SEU in the memory cell. The example memory circuit architectures described herein may include a memory cell that is coupled to a detector circuit. The detector circuit is capable of detecting the occurrence of an SEU in the memory cell. In response to detecting the SEU, the detector circuit is capable of generating an indicator signal indicating that an SEU was detected. Generation of the indicator signal is directly responsive to occurrence of the SEU in the memory cell.

In one or more examples, the indicator signal(s) generated by the detector circuit may be used to trigger other functions within the IC. For example, a read back function may be triggered in response to the indicator signal to correct data within the particular memory cell(s) in which the SEU was detected. This means that the read back function for a memory cell may be controlled, or triggered, by the detector circuit of the memory circuit architecture. Rather than performing read back across all memory cells of the device on a periodic basis, read back may be performed in a targeted and on-demand manner. Read back may be performed only on the particular memory cell or memory cells in which the SEU(s) were detected. Alternatively, read back may be performed for a subset of memory cells that include the memory cell(s) for which an SEU was detected.

In one or more implementations, the example memory circuit architectures may include a correction circuit. A correction circuit may be adapted to correct an output signal generated by the memory cell in cases where an SEU has been detected. The correction circuit allows the memory circuit architecture to output a correct value specified as a corrected output signal despite the original output signal of the memory cell having been compromised by an SEU. Because the detector circuit is also capable of generating the indicator signal, the memory circuit architecture may continue operation by outputting a correct value (e.g., the corrected output signal) at least until read back may be performed on the memory cell that experienced the SEU.

Further aspects of the disclosed technology are described below with reference to the figures. For purposes of simplicity and clarity of illustration, elements shown in the figures have not necessarily been drawn to scale. For example, the dimensions of some of the elements may be exaggerated relative to other elements for clarity. Further, where considered appropriate, reference numbers are repeated among the figures to indicate corresponding, analogous, or like features.

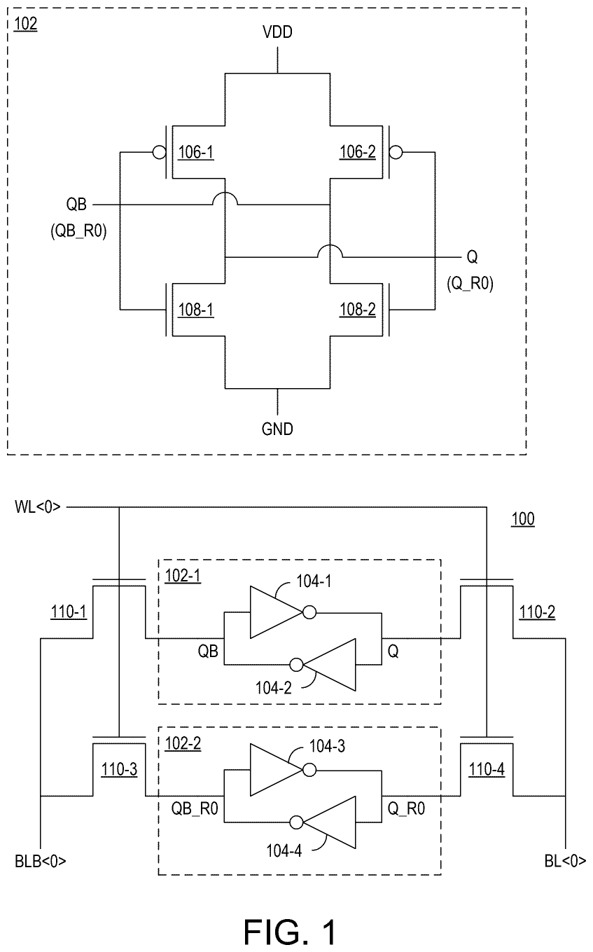

FIG. 1 illustrates an example memory cell 100 of a memory circuit architecture in accordance with one or more implementations of the disclosed technology. Memory cell 100 is an example of a static random-access memory (SRAM) cell. In the example, memory cell 100 is formed using complementary metal-oxide semiconductor (CMOS) transistors. In other examples, other fabrication technologies may be used. As an illustrative and non-limiting example, Germanium transistors may be used to implement the memory cell.

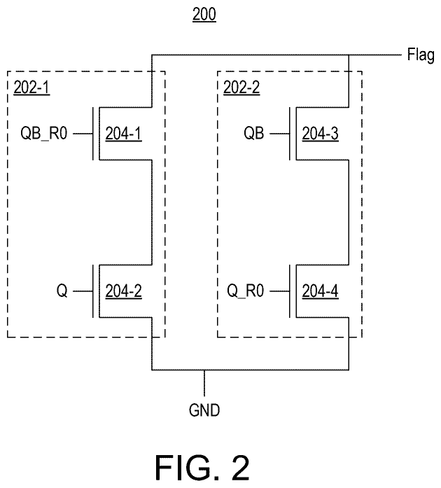

Memory cell 100 of FIG. 1 is capable of operating in cooperation or coordination with a detector circuit described in greater detail in connection with FIG. 2. The detector circuit is capable of detecting an occurrence of an SEU in memory cell 100. In the example of FIG. 1, memory cell 100 of FIG. 1 is not utilized with a correction circuit as described herein in greater detail below.

As illustrated, memory cell 100 includes a plurality of inverter pairs 102. The inverter pairs include a first inverter pair 102-1 and one or more reference inverter pairs illustrated as inverter pair 102-2. The implementation illustrated in FIG. 1 may be limited to including only two inverter pairs. Inverter pair 102-1, also referred to herein as the “first inverter pair,” includes inverter 104-1 and inverter 104-2. Further, inverter pair 102-1 includes nodes labeled Q and QB (Q-bar). Node Q is also referred to herein as the “output node” of memory cell 100. Node Q, being the output node, is the node from which the output signal or output voltage of memory cell 100 is taken. Node QB is also referred to herein as the “inverted output node” in that node QB will have a voltage that is the inverse or opposite of node Q.

Inverter pair 102-2, also referred to herein as the “second inverter pair,” includes inverter 104-3 and inverter 104-4. Inverter pair 102-2 includes nodes labeled Q_R0 and QB_R0. Node Q_R0 is also referred to herein as the “first reference output node” of memory cell 100 and will have a voltage that is the inverse of node QB_R0. Node QB_R0 is also referred to herein as the “first inverted reference output node.” Under normal operating conditions, i.e., where an SEU has not occurred, the voltage of node Q will be equal, or substantially equal, to the voltage of node Q_R0. Similarly, the voltage of node QB will be equal, or substantially equal, to the voltage of node QB_R0. Because inverter pair 102-2 is effectively a copy of inverter pair 102-1, inverter pair 102-2 is referred to as a reference inverter pair. Based on the foregoing, it can be seen that the voltage of node Q will be the inverse or opposite of the voltage of node QB_R0, while the voltage of QB will be the inverse of the voltage of node Q_R0.

In one or more implementations, inverter pair 102-2 is a duplicate of inverter pair 102-1. Further inverters 104 may be matched or duplicates in that each inverter may be created using matched transistors. In an example, the transistors that form inverter 104-1 may be matched to the transistors that form inverter 104-2, inverter 104-3, and inverter 104-4. An example implementation of an inverter pair 102, whether inverter pair 102-1 or inverter pair 102-2, is illustrated in FIG. 1. As shown, the example inverter pair 102 includes p-channel transistors 106-1, 106-2 and n-channel transistors 108-1 and 108-2. The locations of the nodes Q, which corresponds to node Q_R0, and QB, which corresponds to node QB_R0, are also illustrated.

As shown, the plurality of inverter pairs 102 are coupled by access transistors 110 to same bit lines and to a same word line. In the example, the access transistors are n-channel transistors shown as access transistors 110-1, 110-2, 110-3, and 110-4. Access transistors 110-1 and 110-2 are coupled to inverter pair 102-1. Access transistors 110-3 and 110-4 are coupled to inverter pair 102-2. In the example, the drains of the access transistors 110 are coupled to the bit lines while the gates are connected to the word line. For example, the drains of access transistors 110-1 and 110-3 are coupled to the bit line bar (BLB) while the drains of access transistors 110-2 and 110-4 are coupled to the bit line (BL). The gate of each of access transistors 110-1, 110-2, 110-3, and 110-4 is coupled to the word line (WL).

FIG. 2 illustrates an example detector circuit 200 of a memory circuit architecture in accordance with one or more implementations of the disclosed technology. In the example of FIG. 2, detector circuit 200 is coupled to memory cell 100 of FIG. 1 and, during operation, is capable of detecting an occurrence of an SEU in memory cell 100. In response to detecting an SEU in memory cell 100, detector circuit 200 is capable of generating an indicator signal illustrated in FIG. 2 as the “flag” signal. In the example of FIG. 2, generation of (e.g., assertion of) the indicator signal, or the flag signal, occurs with the flag signal going low or being pulled down.

As illustrated, detector circuit 200 includes a plurality of transistor pairs 202. The plurality of transistor pairs include transistor pair 202-1 and transistor pair 202-2. Each transistor pair 202 includes two n-channel, CMOS transistors arranged in series (e.g., with the source of the top transistor connected to the drain of the bottom transistor in the pair). For example, transistor pair 202-1 includes transistors 204-1 and 204-2. Transistor pair 202-2 includes transistors 204-3 and 204-4. Each transistor pair 202 may be matched. Each transistor pair 202 may be referred to as a pair of series transistors.

The gates of transistor 204-1, transistor 204-2, transistor 204-3, and transistor 204-4 are coupled to nodes in memory cell 100 as illustrated. The gate of transistor 204-1 is connected to node QB_R0. The gate of transistor 204-2 is connected to node Q. The gate of transistor 204-3 is connected to node QB. The gate of transistor 204-4 is connected to node Q_R0. This arrangement means that each transistor pair 202 obtains one control signal from inverter pair 102-1 and one control signal from inverter pair 102-2.

Under normal conditions without any SEU having occurred, the voltages applied to the gates of transistors 204 in the same transistor pair 202 will be opposite voltages (inverses of one another). Accordingly, under normal conditions with no SEU having occurred, each transistor pair 202 will have one transistor turned on due to the high voltage applied to the gate and the other transistor turned off due to the low voltage applied to the gate. Thus, under normal conditions with no SEU having occurred in memory cell 100, the flag remains high as neither transistor pair 202-1 nor 202-2 provides a path to ground.

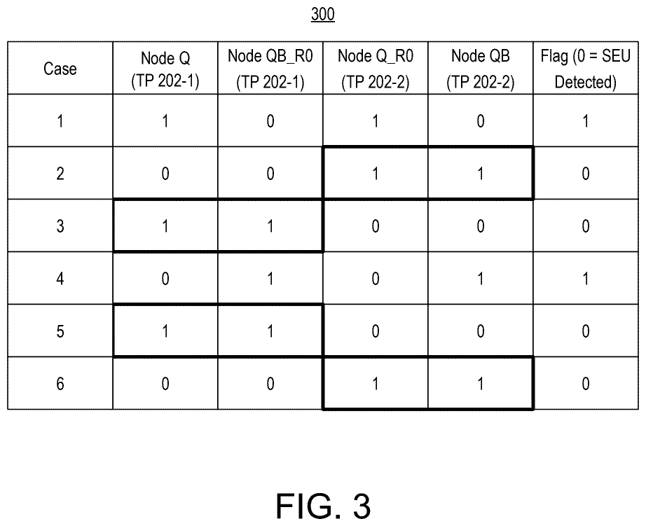

FIG. 3 illustrates a table 300 depicting different scenarios in which the flag signal is triggered in accordance with one or more implementations of the disclosed technology. In the event of an SEU occurring in either inverter pair 102-1 or inverter pair 102-2, the condition described above will not hold and a path to ground will open through one of transistor pairs 202 pulling the flag signal low indicating the occurrence of an SEU in memory cell 100. For example, in the case where memory cell 100 stores a “1” or logic high under normal operating conditions (i.e., no SEU has occurred corresponding to case 1), node Q is high, node QB_R0 is low, node QB is low, and node Q_R0 is high. In response to an SEU changing (e.g., flipping) the state of inverter pair 102-1 (corresponding to case 2), node Q is flipped low, node QB_R0 remains low, node QB is flipped high, and node Q_R0 remains high. Thus, transistor pair 202-2 provides a path to ground pulling the flag signal low.

A similar response occurs in the case where the SEU occurs in inverter pair 102-2 (corresponding to case 3). In that case, node Q remains high, node QB_R0 is flipped high, node QB remains low, and node Q_R0 is flipped low. In this case, transistor pair 202-1 provides a path to ground pulling the flag signal low. Case 4 illustrates a scenario in which memory cell 100 stores a “0” or logic low under normal operating conditions. Cases 5 and 6 illustrate SEUs occurring and being detected.

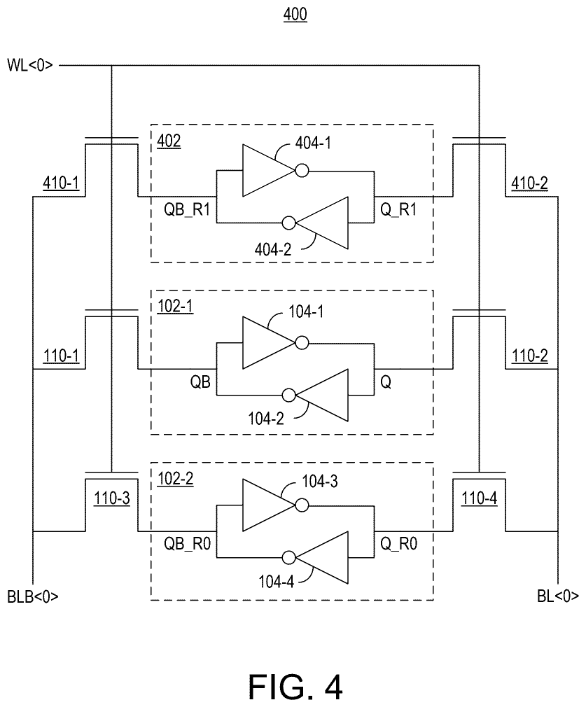

FIG. 4 illustrates another example memory cell 400 of a memory circuit architecture in accordance with one or more implementations of the disclosed technology. Memory cell 400 is substantially similar to memory cell 100 of FIG. 1. In the example of FIG. 4, an additional inverter pair 402 is included having inverters 404-1 and 404-2. Inverter pair 402, like inverter pairs 102, are cross-coupled inverter pairs. Further, the inverters 404 may be matched to inverters 104. Inverter pair 402 is coupled to bit lines BLB and BL via access transistors 410. The gate of each access transistor 410 is coupled to the word line.

Inverter pair 402, also referred to herein as the “third inverter pair,” includes inverter 404-1 and inverter 404-2. Inverter pair 402 includes nodes labeled Q_R1 and QB_R1. Node Q_R1 is also referred to herein as the “second reference output node” of memory cell 400 and will have a voltage that is the inverse of node QB_R1. Node QB_R1 is also referred to as the “second inverted reference output node.” Under normal operating conditions, i.e., where an SEU has not occurred, the voltage of node Q will be equal, or substantially equal, to the voltage of node Q_R1. Similarly, the voltage of node QB will be equal, or substantially equal, to the voltage of node QB_R1. Based on the foregoing, it can be seen that the voltage of node Q will be the inverse or opposite of the voltage of node QB_R1, while the voltage of QB will be the inverse of the voltage of node Q_R1.

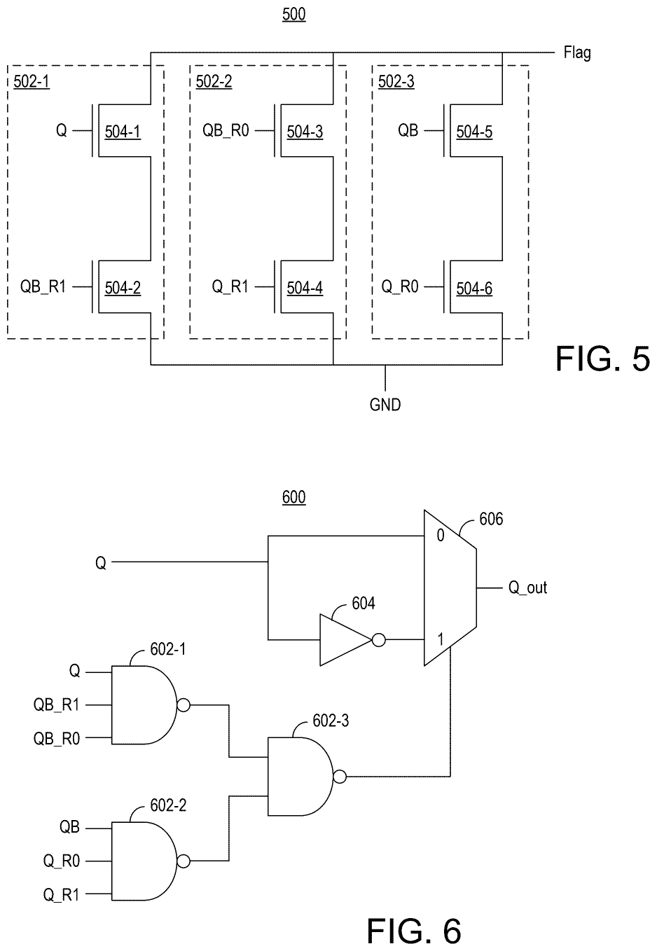

FIG. 5 illustrates an example detector circuit 500 of a memory circuit architecture in accordance with one or more implementations of the disclosed technology. Detector circuit 500 may be used with the memory cell 400 of FIG. 4. In this regard, detector circuit 500 includes three transistor pairs rather than two.

In the example of FIG. 5, detector circuit 500 is coupled to memory cell 400 of FIG. 1 and, during operation, is capable of detecting an occurrence of an SEU in memory cell 400. In response to detecting an SEU in memory cell 400, detector circuit 500 is capable of generating an indicator signal illustrated in FIG. 5 as the “flag” signal. In the example of FIG. 5, generation of the indicator signal, or the flag signal, occurs with the flag signal going low or being pulled down.

As illustrated, detector circuit 500 includes a plurality of transistor pairs 502. The plurality of transistor pairs include transistor pair 502-1, transistor pair 502-2, and transistor pair 502-3. Each transistor pair 502 includes two n-channel, CMOS transistors arranged in series (e.g., with the source of the top transistor connected to the drain of the bottom transistor in the pair). For example, transistor pair 502-1 includes transistors 504-1 and 504-2. Transistor pair 502-2 includes transistors 504-3 and 504-4. Transistor pair 502-3 includes transistors 504-5 and 504-6.

The gates of transistor 504-1, transistor 504-2, transistor 504-3, transistor 504-4, transistor 504-5, and transistor 504-6 are coupled to nodes in memory cell 400 as illustrated. The gate of transistor 504-1 is connected to node Q. The gate of transistor 504-2 is connected to node QB_R1. The gate of transistor 504-3 is connected to node QB_R0. The gate of transistor 504-4 is connected to node Q_R1. The gate of transistor 504-5 is connected to node QB. The gate of transistor 504-6 is connected to node Q_R0. This arrangement means that each transistor pair 502 obtains control signals from a different pairing of inverter pairs. For example, transistor pair 502-1 receives control signals from inverter pairs 102-1 and 402. Transistor pair 502-2 receives control signals from inverter pairs 102-2 and 402. Transistor pair 502-3 receives control signals from inverter pairs 102-1 and 102-2.

FIG. 6 illustrates an example of a correction circuit 600 in accordance with one or more implementations of the disclosed technology. Correction circuit 600 may be used with detector circuit 500 of FIG. 5 and with memory cell 400 of FIG. 4 to correct an incorrect output, i.e., voltage from the node Q, of memory cell 400. In the example of FIG. 6, correction circuit 600 includes a plurality of memory gates implemented as NAND gates 602-1, 602-2, and 602-3, an inverter 604, and a multiplexer 606.

In the example, NAND gates 602 are capable of generating a select, or control, signal that is provided to multiplexer 606 to choose which of the signals provided to inputs 0 and 1 is passed as the output shown as Q_out. The output Q_out is the corrected output signal for memory cell 400. That is, Q_out is a corrected version of the output taken from node Q of memory cell 400. As pictured, NAND gate 602-1 receives three inputs which are node Q, node QB_R1, and node QB_R0. NAND gate 602-2 receives three inputs which are node QB, node Q_R0, and node Q_R1. NAND gate 602-3 receives two input signals which are the output of NAND gate 602-1 and the output of NAND gate 602-2. The output of NAND gate 602-3 is provided as the select signal to multiplexer 606.

As illustrated, input 0 of multiplexer 606 receives the signal taken from node Q of memory cell 400. The same signal is provided to inverter 604. The output of inverter 604 is coupled to input 1 of multiplexer 606. Accordingly, multiplexer 606 passes either Q or QB as Q_out depending on whether an SEU was detected and whether the output signal, e.g., the voltage of node Q, is detected to be incorrect (e.g., has been detected as being flipped due to the occurrence of an SEU).

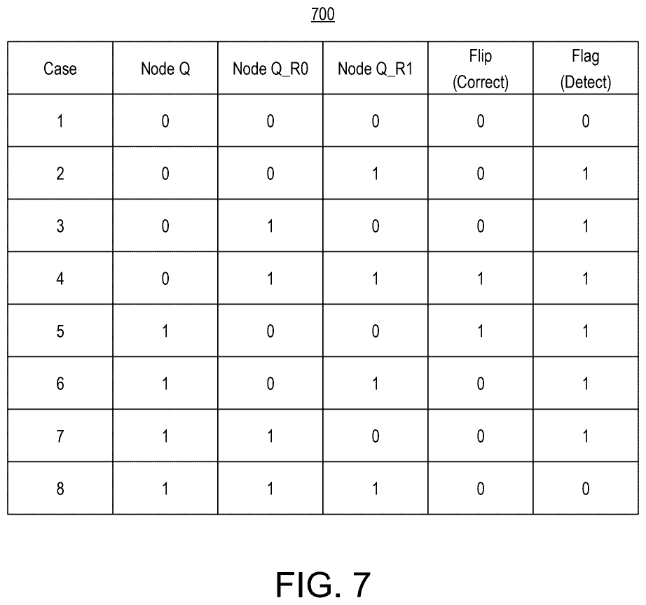

FIG. 7 illustrates a table 700 depicting different scenarios in which the memory cell output is corrected and the flag signal is triggered in accordance with one or more implementations of the disclosed technology. Table 700 illustrates behavior of a memory circuit architecture formed of memory cell 400, detector circuit 500, and correction circuit 600.

In the example, only cases 1 and 8 represent scenarios in which no SEU was detected. In each of case 1 and 8, detector circuit 500 did not detect an SEU and correction circuit 600 did not correct, or change, the output of memory cell 400 (node Q). For purposes of illustration, the flag (detect) column illustrates inverted logic relative to asserting the flag signal (pulling down). Thus, 0 values indicate that the flag signal was not asserted (e.g., was not pulled down) and are indicative of no SEU having been detected. The flip (correct) column illustrates the state of the select signal provided to multiplexer 606 from NAND gate 602-3. Thus, a 0 value in the flip (correct) column indicates that the signal from node Q (Q) of memory cell 400 is passed unaltered by correction circuit 600 (input 0 is passed by multiplexer 606) while a 1 value in the flip (correct) column indicates that an inverted version of the signal from node Q (QB) is passed by correction circuit 600 (input 1 is passed by multiplexer 606).

Table 700 illustrates that in each of cases 2, 3, 4, 5, 6, and 7, an SEU was detected. For example, in each of cases 2, 3, 4, 5, 6, and 7, at least one of node Q, node Q_R0, and node Q_R1 does not match, which indicates the occurrence of an SEU in memory cell 400. Only in cases 4 and 5, however, does correction circuit 600 correct the output from memory cell 400. In each of cases 4 and 5, both nodes Q_R0 and Q_R1 match with node Q being the mismatch indicating that the SEU has corrupted the output of memory cell 400.

It should be appreciated that the memory circuit architectures described herein may implement a read back function to ensure that the memory cell stores the correct value or state in response to assertion of the flag signal indicating the occurrence of an SEU. This behavior, i.e., initiating read back in response to a detected SEU, may be implemented in the example memory circuit architecture of FIGS. 1, 2, and 3 and also in the memory circuit architecture of FIGS. 4, 5, 6, and 7. The memory circuit architecture of FIGS. 4, 5, 6, and 7 is capable of correcting the output of memory cell 400 in those cases where that output is considered corrupted as illustrated in FIG. 7.

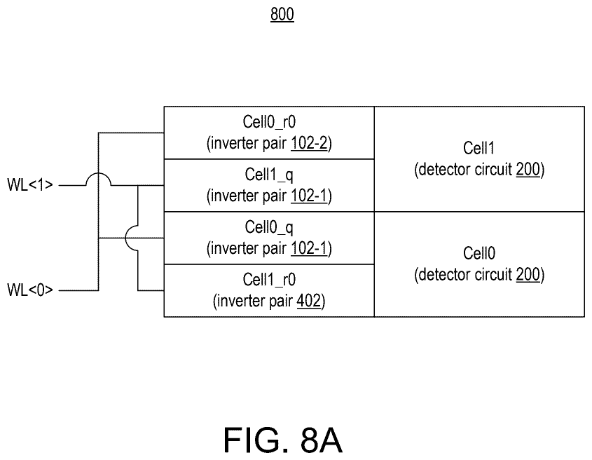

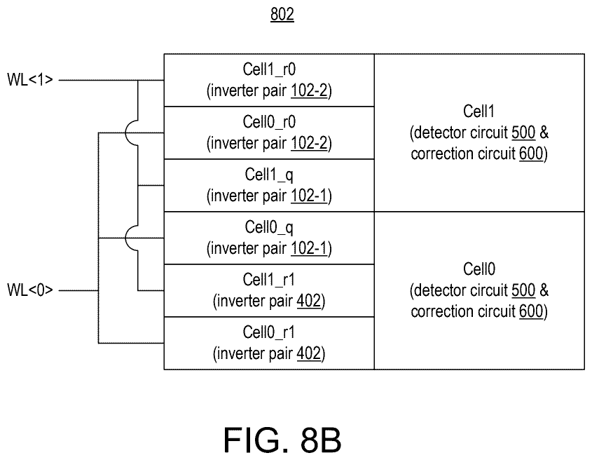

FIGS. 8A and 8B illustrate example layouts of a memory circuit architecture in accordance with one or more implementations of the disclosed technology. FIG. 8A illustrates an example layout 800 of a memory circuit architecture that is capable of detecting an occurrence of an SEU in a memory cell therein in accordance with one or more implementations of the disclosed technology. The example of FIG. 8A may be used with the memory circuit architecture formed of memory cell 100 and detector circuit 200. The example of FIG. 8A illustrates how different portions of two different instances of such a memory circuit architecture labeled as 0 and 1 may be implemented on an IC. In the example, different inverter pairs for each memory circuit architecture instance are referred to as a “cell.”

In the example, the ordering of cells from top to bottom is as follows: cell0_r0 (representing inverter pair 102-2 of memory circuit architecture 0), cell1_q (representing inverter pair 102-1 of memory circuit architecture 1), cell0_q (representing inverter pair 102-1 of memory circuit architecture 0), and cell1_r0 (representing inverter pair 102-2 of memory circuit architecture 1). As illustrated, cell0_r0 abuts (e.g., is adjacent to), cell1_q, which abuts cell0_q, which abuts cell1_r0.

In the example, detector circuit 200 of memory circuit architecture 1 abuts cell0_ r0 and cell1_q. Detector circuit 200 of memory circuit architecture 0 abuts cell0_q and cell1_r0. As may be observed, different portions of memory circuit architecture 0 and memory circuit architecture 1 are interdigitated (e.g., alternate).

FIG. 8B illustrates another example layout 802 of a memory circuit architecture that is capable of correcting the output of a memory cell therein in accordance with one or more implementations of the disclosed technology. The example of FIG. 8B may be used with the memory circuit architecture formed of memory cell 400, detector circuit 500, and correction circuit 600. The example of FIG. 8 illustrates how different portions of two different instances of such a memory circuit architecture labeled as 0 and 1 may be implemented on an IC. In the example, different inverter pairs for each memory circuit architecture instance are referred to as a “cell.”

In the example, the ordering of cells from top to bottom is as follows: cell1_r0 (representing inverter pair 102-2 of memory circuit architecture 1), cell0_r0 (representing inverter pair 102-2 of memory circuit architecture 0), cell1_q (representing inverter pair 102-1 of memory circuit architecture 1), cell0_q (representing inverter pair 102-1 of memory circuit architecture 0), cell1_r1 (representing inverter pair 402 of memory circuit architecture 1), and cell0_r1 (representing inverter pair 402 of memory circuit architecture 0). As illustrated, cell1_r0 abuts (e.g., is adjacent to), cell0_r0, which abuts cell1_q, which abuts cell0_q, which abuts cell1_r1, and which abuts cell0_r1.

In the example, correction circuit 600 and detector circuit 500 of memory circuit architecture 1 abut cell1_r0, cell0_r0, and cell1_q. Correction circuit 600 and detector circuit 500 of memory circuit architecture 0 abut cell0_q, cell1_r1, and cell0_r1. As may be observed, different portions of memory circuit architecture 0 and memory circuit architecture 1 are interdigitated (e.g., alternate).

In the examples of FIGS. 8A and 8B, nodes that store the data (e.g., node Q and node Q_R0 in FIG. 8A and node Q, node Q_R0, and node Q_R1 in FIG. 8B) are placed at a minimum distance of one cell height. This layout and the interleaving of portions of the two memory circuit architectures meet SEU requirements specifying a minimum distance between two latch nodes. The interleaving illustrated in FIGS. 8A and 8B eliminates the chance of flipping multiple nodes placed closely by the same SEU event. The example layouts of FIGS. 8A and 8B are also advantageous for other fabrication technologies and technology node sizes such as GAA 2 nm, 1.4 nm, and/or 1 nm technology nodes.

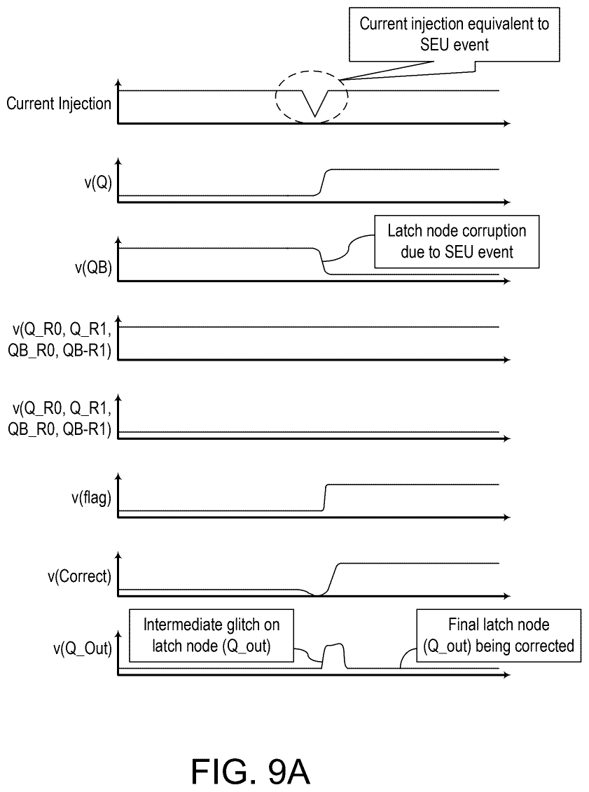

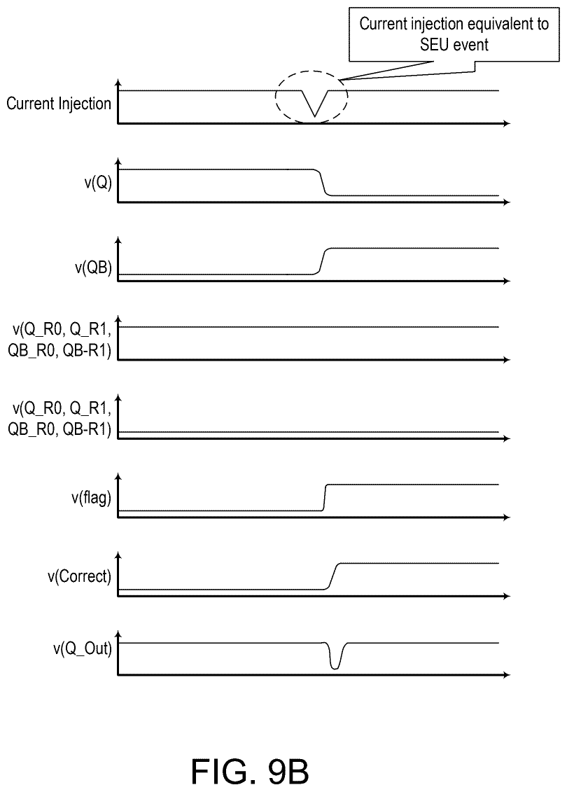

FIGS. 9A and 9B illustrate different signals of the memory circuit architecture of FIGS. 4, 5, 6, and 7 for different conditions. FIG. 9A illustrates signals for different nodes in the case where an SEU occurs at node Q and flips the state of the node from 0 to 1. In FIG. 9A, node Q moves from 0→1, node Q_R 0=0, and node Q_R1=0. In this example, because only one node is affected, the memory circuit architecture that is capable of correction detects the SEU and corrects the data. FIG. 9B illustrates the same situation albeit with node Q storing a 1 and the SEU flipping state of node Q to 0. In the example of FIG. 9B, node Q moves from 1→0, node Q_R0=1, and node Q_R1=1.

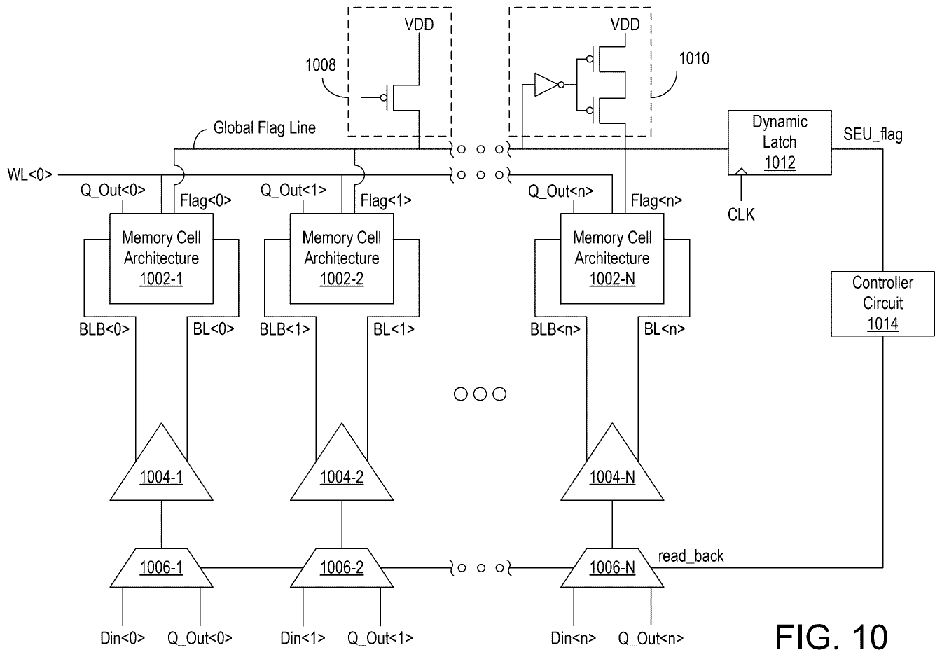

FIG. 10 illustrates an example memory formed of a plurality of instances of the memory circuit architecture described herein in accordance with one or more implementations of the disclosed technology. In the example, each of memory circuit architectures 1002-1, 1002-2, through 1002-N (e.g., instances thereof), where “N” is an integer value greater than 1, may be implemented as the memory circuit architecture formed of memory cell 400, detector circuit 500, and correction circuit 600. Each instance of memory circuit architecture 1002 is driven by a driver circuit 1004. Each driver circuit 1004 receives an input signal from a multiplexer 1006 that is capable of switching to pass a data value Din or a read back value Q_out based on the select signal provided to the multiplexer 1006 illustrated as the “read_back” signal.

In the example of FIG. 10, each Q_out signal is the output node of correction circuit 600 for that instance and, as such, will output a correct value. The corrected value Q_out may be used as the correct output, but also for performing read back in a next clock cycle as the correct value to store in the respective instances of memory circuit architectures 1002. The Q_out node corresponds to the latch node of FIGS. 9A and 9B. As shown, each individual flag signal (“Flag”) from the individual instances of memory circuit architecture 1002 is coupled to a global flag line that is maintained in a high state by pre-charge circuit 1008 and keeper circuit 1010. Any of the individual flag signals from any instance of memory circuit architecture 1002 being asserted (e.g., going low) will assert (e.g., pull down) the global flag line.

An SEU may occur in one or in multiple memory circuit architecture diffusion regions and change the state of the data. In either case, the Flag<*>will drag down the global flag line, which is always pre-charged to a logic high. The state of the global flag line will be captured by dynamic latch 1012 at each clock edge and fetched/output as the SEU_flag. The state of SEU_flag is a global flag that indicates whether an SEU has occurred that may corrupt the correct behavior of the circuit design or system.

In the example, the read back function may be initiated as needed in that read back may be initiated in response to the SEU_flag being asserted (e.g., going low). For example, a controller circuit 1014 may be coupled to the SEU_flag that initiates the read back function for each instance of memory circuit architecture 1002 connected to the global flag line (e.g., the same global flag line). In one or more examples, controller circuit 1014 may initiate the read back function in the clock cycle immediately following the clock cycle in which the SEU_flag is asserted. This means that read back need only be performed in response to an actual detected SEU as opposed to being performed automatically and on a period basis regardless of need or the occurrence of an SEU, which can save significant power within a device.

The example memory circuit architectures described herein may be used to implement any of a variety of memory circuits and/or SRAM. Example memories circuits and/or circuit blocks that may be implemented using the memory circuit architectures described herein may include, but are not limited to, block RAM, Ultra-RAMs, programmable interconnects, and/or other configurable logic elements and/or registers as may be included in any of a variety of ICs whether Application-Specific ICs, programmable ICs including Field Programmable Gate Arrays (FPGAs), or the like.

In one or more other example implementations, the architecture illustrated in FIG. 10 may be implemented using a memory circuit architecture formed of memory cell 100 and detector circuit 200. In that case, the instances of the memory circuit architecture will not have a Q_out, but rather an output node Q. Still, the SEU detection may operate as described and may be used to initiate the read back function as needed in response to detection of an SEU.

In the examples above, the read back function may be performed on any group of instances of the particular memory circuit architecture used that are grouped together to generate the SEU_flag (the global flag). In some arrangements, the global flag may not be used allowing read back to be performed on only the particular instance of the memory circuit architecture that asserted a local flag (e.g., “Flag<n>”). In other cases, a plurality of groups, with each group including a plurality of instances of the memory circuit architecture may be formed such that a plurality of global flags are used in an IC with each global flag corresponding to a particular subset of instances of the memory circuit architecture. In this example, read back need only be performed on the subset of instances of the memory circuit architecture that include the particular instance of the memory circuit architecture that experienced the SEU.

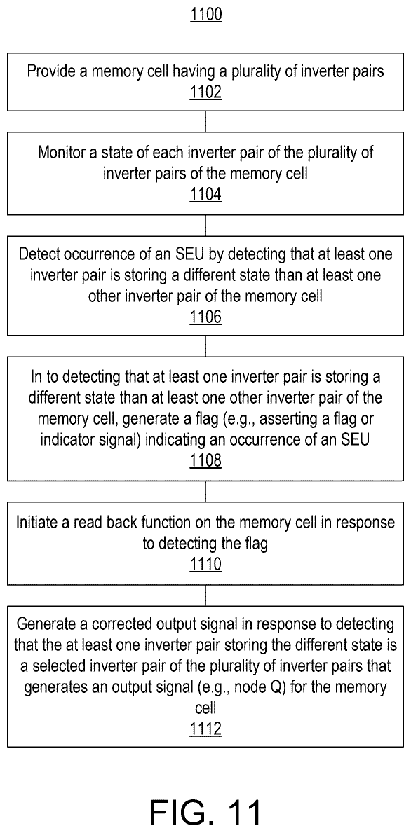

FIG. 11 illustrates a method 1100 of operation of a memory circuit architecture in accordance with one or more implementations of the disclosed technology. In block 1102, a memory cell 100, 400 having a plurality of inverter pairs is provided. Each inverter pair of the plurality of inverter pairs is coupled to same bit lines and to a same word line. Further, under normal operating conditions (e.g., where no SEU has occurred or been detected), each inverter pair stores a same state. That is, like nodes (e.g., like nodes Q, Q_R0, and/or Q_R1 and like nodes QB, QB_R0, and/or QB_R1) of each inverter pair of the plurality of inverter pairs have a same or substantially same voltage.

In block 1104, the state of each inverter pair of the memory cell is monitored during operation by a detector circuit 200, 500. The detector circuit is capable of comparing the states of the plurality of inverter pairs. In block 1106, the detector circuit is capable of detecting the occurrence of an SEU by detecting that at least one inverter pair is storing a different state than at least one other inverter pair of the memory cell. In block 1108, in response to detecting that at least one inverter pair is storing a different state than at least one other inverter pair of the memory cell, the detector circuit is capable of generating a flag (e.g., asserting a flag or indicator signal) indicating an occurrence of an SEU.

In block 1110, a controller circuit 1014 is capable of initiating a read back function on the memory cell in response to detecting the flag. In one or more examples, the read back function is implemented only for a subset of one or more instances of a memory circuit architecture of a plurality of instances of the memory circuit architecture that include the memory cell in which the SEU was detected.

In the case where the memory circuit architecture does not include a correction circuit, the read back function may write back a reference value stored as reference data that is available to the electronic system or IC for purposes of performing read back for each instance of the memory circuit architecture. In the case where the memory circuit architecture does include a correction circuit, the corrected output signal (Q_out) may be written back to the respective instances of the memory circuit architecture.

In block 1112, correction circuit 600 is capable of generating a corrected output signal in response to detecting that the at least one inverter pair storing the different state is a selected inverter pair of the plurality of inverter pairs that generates an output signal (e.g., node Q) for the memory cell 400. Block 1112 may be omitted for the memory circuit architectures that do not include a correction circuit.

The terminology used herein is for the purpose of describing particular examples only and is not intended to be limiting. Notwithstanding, several definitions that apply throughout this document are expressly defined as follows.

As defined herein, the singular forms “a,” “an,” and “the” are intended to include the plural forms as well, unless the context clearly indicates otherwise.

As defined herein, the term “approximately” means nearly correct or exact, close in value or amount but not precise. For example, the term “approximately” may mean that the recited characteristic, parameter, or value is within a predetermined amount of the exact characteristic, parameter, or value.

As defined herein, the terms “at least one,” “one or more,” and “and/or,” are open-ended expressions that are both conjunctive and disjunctive in operation unless explicitly stated otherwise.

As defined herein, the term “automatically” means without human intervention.

As defined herein, the phrase “in response to” and the phrase “responsive to” means responding or reacting readily to an action or event. The response or reaction is performed automatically. Thus, if a second action is performed “responsive to” a first action, there is a causal relationship between an occurrence of the first action and an occurrence of the second action. The term “responsive to” indicates the causal relationship.

As defined herein, the term “substantially” means that the recited characteristic, parameter, or value need not be achieved exactly, but that deviations or variations, including for example, tolerances, measurement error, measurement accuracy limitations, and other factors known to those of skill in the art, may occur in amounts that do not preclude the effect the characteristic was intended to provide.

The terms first, second, etc., may be used herein to describe various elements. These elements should not be limited by these terms, as these terms are only used to distinguish one element from another unless stated otherwise or the context clearly indicates otherwise.

In some alternative implementations, the operations noted in the blocks may occur out of the order noted in the figures. For example, two blocks shown in succession may be executed substantially concurrently, or the blocks may sometimes be executed in the reverse order, depending upon the functionality involved. In other examples, blocks may be performed generally in increasing numeric order while in still other examples, one or more blocks may be performed in varying order with the results being stored and utilized in subsequent or other blocks that do not immediately follow. It will also be noted that each block of the block diagrams and/or flowchart illustration, and combinations of blocks in the block diagrams and/or flowchart illustration, may be implemented by special purpose hardware-based systems that perform the specified functions or acts or carry out combinations of special purpose hardware and computer instructions.

The descriptions of the various implementations of the disclosed technology have been presented for purposes of illustration, but are not intended to be exhaustive or limited to the examples disclosed. Many modifications and variations will be apparent to those of ordinary skill in the art without departing from the scope and spirit of the described examples. The terminology used herein was chosen to best explain the principles of the examples, the practical application or technical improvement over technologies found in the marketplace, or to enable others of ordinary skill in the art to understand the examples disclosed herein.

What is claimed is:

1. A memory circuit, comprising:
a memory cell comprising a plurality of inverter pairs including a first inverter pair and one or more reference inverter pairs;
wherein the plurality of inverter pairs are coupled by access transistors to same bit lines and to a same word line; and
a detector circuit coupled to the plurality of inverter pairs, wherein the detector circuit is capable of generating an indicator signal in response to detecting a single-event upset (SEU) in the memory cell by detecting a mismatch in stored states among the plurality of inverter pairs of the memory cell.

2. The memory circuit of claim 1, wherein each inverter pair of the plurality of inverter pairs is cross-coupled.

3. The memory circuit of claim 1, wherein the one or more reference inverter pairs include a second inverter pair; and
wherein the detector circuit is coupled to an output node and an inverted output node of the first inverter pair and is coupled to a first reference output node and a first inverted reference output node of the second inverter pair.

4. The memory circuit of claim 3, wherein the detector circuit comprises:
a first pair of series transistors coupled to the first inverted reference output node of the second inverter pair and the output node of the first inverter pair; and
a second pair of series transistors coupled to the inverted output node of the first inverter pair and the first reference output node of the second inverter pair.

5. The memory circuit of claim 4, wherein a gate of a first transistor of the first pair of series transistors is coupled to the first inverted reference output node;
a gate of a second transistor of the first pair of series transistors is coupled to the output node;
a gate of a first transistor of the second pair of series transistors is coupled to the inverted output node; and
a gate of a second transistor of the second pair of series transistors is coupled to the first reference output node.

6. The memory circuit of claim 3, wherein the one or more reference inverter pairs include a third inverter pair and the output node provides an output signal from the memory cell; and
wherein the memory circuit further comprises:
a correction circuit coupled to the output node and capable of outputting a corrected output signal for the memory cell.

7. The memory circuit of claim 6, wherein the third inverter pair is cross-coupled.

8. The memory circuit of claim 6, wherein the correction circuit is capable of generating the corrected output signal as a function of signals from the output node, the inverted output node, the first reference output node, and the first inverted reference output node, and a second reference output node of the third inverter pair and a second inverted reference output node of the third inverter pair.

9. The memory circuit of claim 8, wherein the detector circuit comprises:
a first pair of series transistors coupled to the output node and the second inverted reference output node;
a second pair of series transistors coupled to the first inverted reference output node and the second reference output node; and
a third pair of series transistors coupled to the inverted output node and the first reference output node.

10. The memory circuit of claim 9, wherein a gate of a first transistor of the first pair of series transistors is coupled to the output node;
a gate of a second transistor of the first pair of series transistors is coupled to the second inverted reference output node;
a gate of a first transistor of the second pair of series transistors is coupled to the first inverted reference output node;
a gate of a second transistor of the second pair of series transistors is coupled to the second reference output node;
a gate of a first transistor of the third pair of series transistors is coupled to the inverted output node; and
a gate of a second transistor of the third pair of series transistors is coupled to the first reference output node.

11. The memory circuit of claim 1, wherein a controller circuit is capable of initiating a read back function on the memory cell in response to detecting the indicator signal.

12. A method comprising:
providing a memory cell having a plurality of inverter pairs;
wherein each inverter pair is coupled to same bit lines and to a same word line and stores a same state;
monitoring the state of each inverter pair of the memory cell during operation by a detector circuit comparing the states of plurality of inverter pairs; and
in response to detecting that at least one inverter pair is storing a different state than at least one other inverter pair of the memory cell, the detector circuit generating a flag indicating an occurrence of a single-event upset (SEU).

13. The method of claim 12, further comprising:
initiating a read back function on the memory cell in response to detecting the flag.

14. The method of claim 13, wherein the read back function is implemented only for a subset of one or more instances of a memory circuit architecture of a plurality of instances of the memory circuit architecture that include the memory cell in which the SEU was detected.

15. The method of claim 12, wherein the plurality of inverter pairs of the memory cell include a first inverter pair and a second inverter pair; and
wherein each inverter pair is cross-coupled.

16. The method of claim 15, wherein the detector circuit comprises:
a first pair of series transistors coupled to an inverted reference output node of the second inverter pair and an output node of the first inverter pair; and
a second pair of series transistors coupled to an inverted output node of the first inverter pair and a first reference output node of the second inverter pair.

17. The method of claim 12, further comprising:
generating a corrected output signal in response to detecting that the at least one inverter pair storing the different state is a selected inverter pair of the plurality of inverter pairs that generates an output signal for the memory cell.

18. The method of claim 17, wherein the plurality of inverter pairs of the memory cell include a first inverter pair, a second inverter pair, and a third inverter pair, wherein the second and third inverter pairs are reference inverter pairs; and
wherein the corrected output signal is generated as a function of signals from an output node and an inverted output node of the first inverter pair, a first reference output node and a first inverted reference output node of the second inverter pair, and a second reference output node and a second inverted reference output node of the third inverter pair.

19. An integrated circuit, comprising:
a plurality of instances of a memory circuit architecture, wherein the memory circuit architecture includes:
a memory cell comprising a plurality of inverter pairs including a first inverter pair and one or more reference inverter pairs;
wherein the plurality of inverter pairs are coupled by access transistors to same bit lines and to a same word line;
a detector circuit coupled to the plurality of inverter pairs, wherein the detector circuit is capable of generating an indicator signal in response to detecting a single-event upset (SEU) in the memory cell by detecting a mismatch in stored states among the plurality of inverter pairs of the memory cell; and
a correction circuit coupled to an output node of the first inverter pair and capable of outputting a corrected output signal for the memory cell;
wherein the plurality of inverter pairs of the plurality of instances of the memory circuit architecture are interdigitated.

20. The integrated circuit of claim 19, wherein a read back function is implemented for at least one instance of the plurality of instances of the memory circuit architecture in which the SEU occurred in response to the indicator signal from the detector circuit.
